(19) United States
(12) Patent Application Publication
(10) Pub. No.: US 2014/0352926 A1
(43) Pub. Date: Dec. 4, 2014

(54) SHELL STRUCTURE FOR HANDHELD DEVICE

(71) Applicant: Cooler Master CO., LTD., New Taipei City (TW)

(72) Inventors: CHIEN-HUNG SUN, NEW TAIPEI CITY (TW); TE-HSUAN CHIN, NEW TAIPEI CITY (TW)

(21) Appl. No.: 13/906,781

(22) Filed: May 31, 2013

(51) Int. Cl. H05K 7/20

(52) U.S. Cl. CPC H05K 7/20336
USPC 165/104.26

(57) ABSTRACT

A shell structure for handheld device includes at least a portion of vapor chamber. The vapor chamber is formed with a heat absorbing portion and a heat dissipating portion. The vapor chamber is vacuumed and filled with fluid. A plurality of capillaries is formed in the vapor chamber. The heat from the handheld device is emitted rapidly by traveling through the vapor chamber without occupying the interior space of the handheld device.

### BACKGROUND

1. Field of the Invention

The instant disclosure relates to a shell structure; in particular, to a shell structure facilitating handheld device heat dissipation and maintaining optimal working temperature.

2. Description of Related Art

Conventional handheld devices (for example, mobile phones, tablets, personal digital assistance, and digital camera) require less power without the need of a heat sink. However, the electronic components still generate considerable amount of heat within the handheld device and the device temperature may climb in the future. Eventually, the installation of heat sink is unavoidable.

To install heat sinks in a handheld device can occupy the relatively limited interior space. As a result, the device volume increases whereas the market requires an ever-thinning handheld device. Furthermore, the heat sinks embedded in the handheld device do not efficiently dissipate the heat and the unwanted heat accumulation usually leads to abnormal device performance.

To address the above issues, the inventor strives via associated experience and research to present the instant disclosure, which can effectively improve upon the limitation described above.

### SUMMARY OF THE INVENTION

The instant disclosure provides a shell structure for handheld device, being able to guide and transfer the heat from the device rapidly without occupying the device interior space. The shell structure is formed with a vapor chamber. The vapor chamber has a receiving face and an emitting face. The vapor chamber defines a vacuumed chamber filled with fluid. A plurality of capillaries is formed in the chamber.

The shell structure of the instant disclosure is entirely or partially formed with a vapor chamber. The recessing face of the vapor chamber contacts those heat generating components in the handheld device and absorbs the heat. The heat is then dissipated to the ambient via the shell structure. The shell structure needs not to be installed inside the handheld device and therefore saves the limited space there-within. The shell structure also has larger area for heat dissipation that accelerates heat transferring.

In order to further understand the instant disclosure, the following embodiments are provided along with illustrations to facilitate the appreciation of the instant disclosure; however, the appended drawings are merely provided for reference and illustration, without any intention to be used for limiting the scope of the instant disclosure.

### BRIEF DESCRIPTION OF THE DRAWINGS

FIG. 1 is a perspective view of a shell structure for handheld device in accordance with a first embodiment of the instant disclosure.

FIG. 2 is a side view of a shell structure for handheld device in accordance with a first embodiment of the instant disclosure.

FIG. 3 is a perspective view of a shell structure for handheld device in accordance with a second embodiment of the instant disclosure.

FIG. 4 is a perspective view of a shell structure for handheld device in accordance with a third embodiment of the instant disclosure.

FIG. 5 is a perspective view of a shell structure for handheld device in accordance with a fourth embodiment of the instant disclosure.

FIG. 6 is a perspective view of a shell structure for handheld device in accordance with a fifth embodiment of the instant disclosure.

### DETAILED DESCRIPTION OF THE PREFERRED EMBODIMENTS

The aforementioned illustrations and following detailed descriptions are exemplary for the purpose of further explaining the scope of the instant disclosure. Other objectives and advantages related to the instant disclosure will be illustrated in the subsequent descriptions and appended drawings.

### First Embodiment

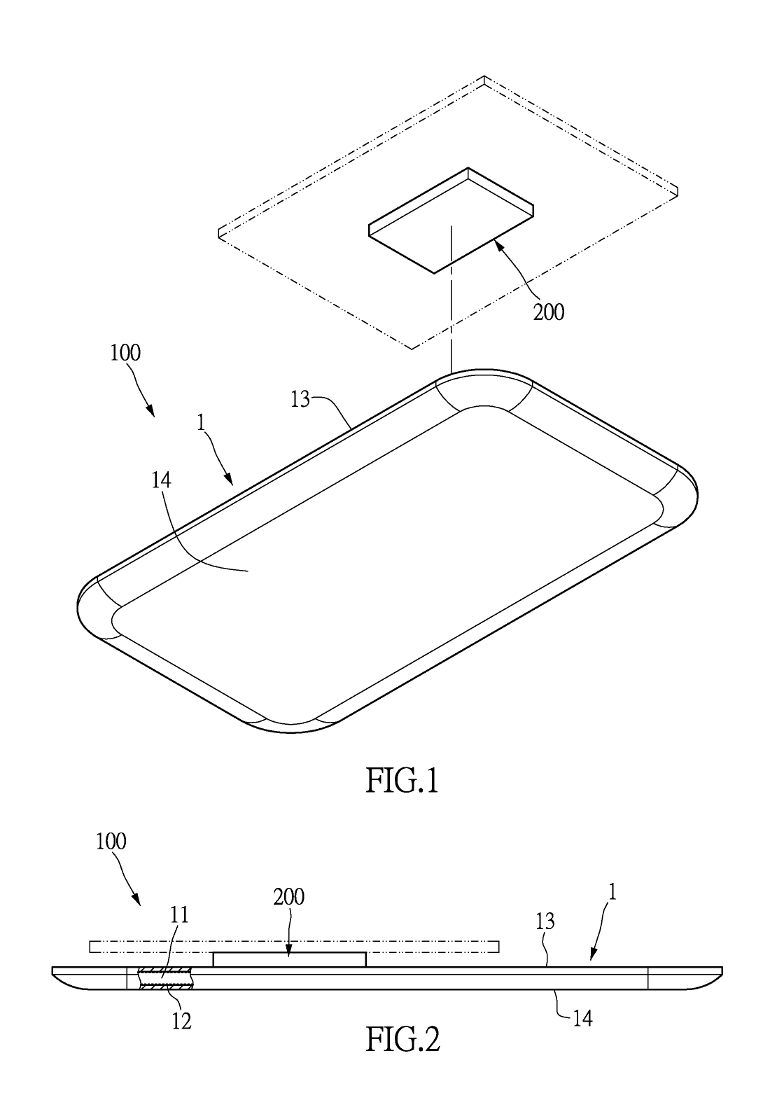

Referring to FIGS. 1 and 2, the instant disclosure provides a shell structure for handheld device. The handheld device can be a mobile phone, a tablet, a laptop, a personal digital assistance, a digital camera, an MP3/MP4 multimedia player, an electronic device for games, or the like. The shell structure 100 can be the back cover, top cover, base or the other portion of the handheld device and the instant disclosure is not limited thereto. In the instant embodiment, the shell structure 100 is the back cover of a mobile phone.

At least one portion of the shell structure 100 is formed with a vapor chamber 1. That is, the entirety or a portion of the shell structure 100 is the vapor chamber 1. In the instant embodiment, the entire shell structure 100 is formed as the vapor chamber 1. In other words, the shell structure 100 defines the vapor chamber 1. The configuration of the vapor chamber 1 is not limited to the instant embodiment. The vapor chamber 1 can be configured to fit the handheld device, for example, being planar, with curve, or any other geometric configuration.

The vapor chamber 1 can be made of copper, aluminum or other metallic material having desirable heat conductivity. In general, the vapor chamber 1 can be fabricated by matching a top cover and a bottom cover that are jointed by welding, diffusion bonding or the like known by a person skilled in the art.

The vapor chamber 1 is formed with a vacuumed cavity 11 filled with fluid (not shown). The fluid can be water, methanol, refrigerant, acetone or ammonium. The phase conversion of the fluid can accelerate heat transfer and dissipation. A plurality of capillaries 12 are formed in the cavity 11. The capillaries 12 can be grooves, grid or formed by powder sintering or the combination thereof. A supporting structure (not shown) may also be formed in the cavity 11 to enhance the structural strength.

Additionally, the shell structure 100 (vapor chamber 1) can be made of deformable materials, therefore enabling the shell structure 100 to be bent.

One side of the vapor chamber 1 serves as a heat absorbing portion 13, and the opposite side as a heat dissipating portion 14. The heat absorbing portion 13 is positioned inside the handheld device while the heat dissipating portion 14 faces the ambient. The heat from a heat generating component 200 (for example, chips or central processor) of the handheld device is transferred to the vapor chamber 1 through the heat absorbing portion 13. The heat dissipating portion 14 may contact the ambient or be connected to another heat dissipation device.

The liquid phase fluid absorbs heat from the heat absorbing portion 13 and converts to steam or gas. The steam or gas condenses over the heat dissipating portion 14 and converts back to liquid phase. The liquid phase fluid returns to the heat absorbing portion 13 through the capillaries 12 inside the cavity 11. The fluid is in a liquid-gas recirculation in the cavity 11 to facilitate heat transferring.

### Second Embodiment

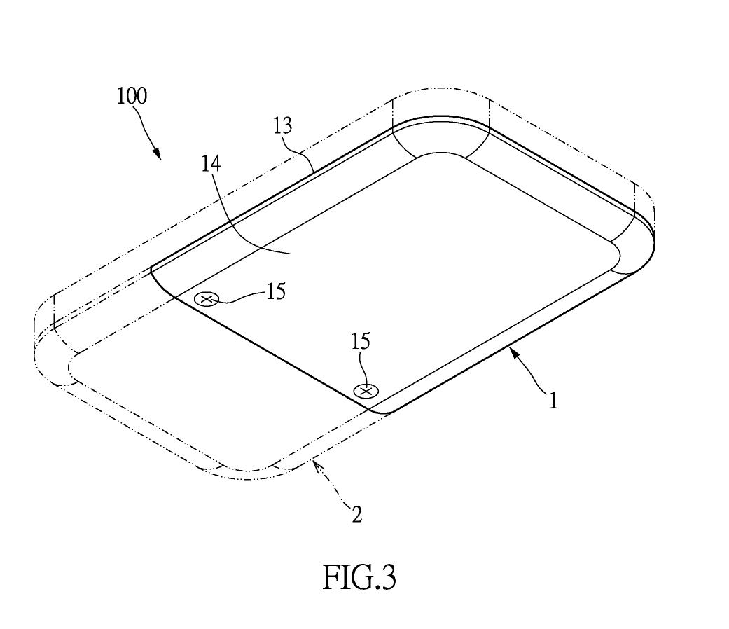

Referring to FIG. 3, a portion of the shell structure 100 is formed with the vapor chamber 1. That is, the shell structure 100 has a casing 2, and the vapor chamber 1 and the casing 2 are formed individually. The vapor chamber 1 and the casing 2 are connected by screws, press fit, plug-in, welding or adhesives. In the instant embodiment, the vapor chamber 1 and the casing 2 are connected by a plurality of screws 15. The vapor chamber 1 and casing 2 are not integrally formed and therefore the material thereof may vary. For example, the casing 2 can be made of metallic or plastic material.

### Third Embodiment

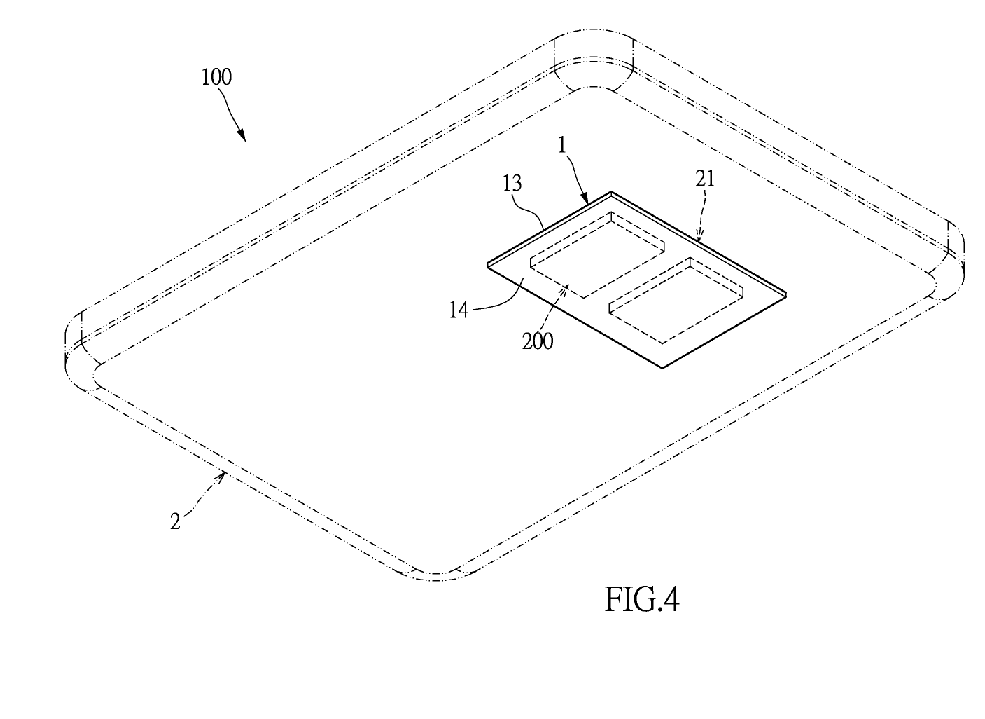

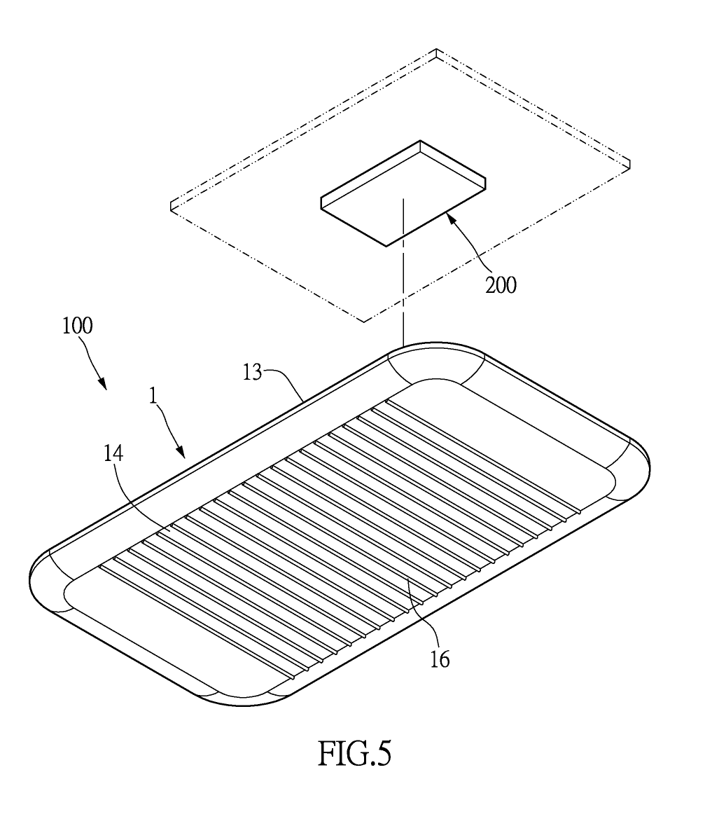

Referring to FIG. 4, in the instant embodiment, the shell structure 100 is the back cover of a tablet. A portion of the shell structure 100 is formed with the vapor chamber 1. That is, the shell structure 100 has the casing 2, and the vapor chamber 1 and the casing 2 are formed individually. The casing 2 is configured to accommodate the vapor chamber 1 therein. The accommodating space 21 is visually integrated with the casing 2. The vapor chamber 1 and the casing 2 can also be connected by screws, press fit, plug-in, welding or adhesives.

In another embodiment of the instant disclosure, the shell structure 100 may have two or more vapor chamber 1 (not shown) accommodated in the casing 2. The vapor chambers 1 are arranged to contact the heat generating components in the handheld device.

### Fourth Embodiment

Referring to FIG. 5, in the instant embodiment, the heat dissipating portion 14 of the vapor chamber 1 is formed with a plurality of fins 16. The fins 16 may be formed on any desirable area over the heat dissipating portion 14 to enhance heat dissipation in the specific area. The fins 16 can improve the heat transferring within the vapor chamber 1.

### Fifth Embodiment

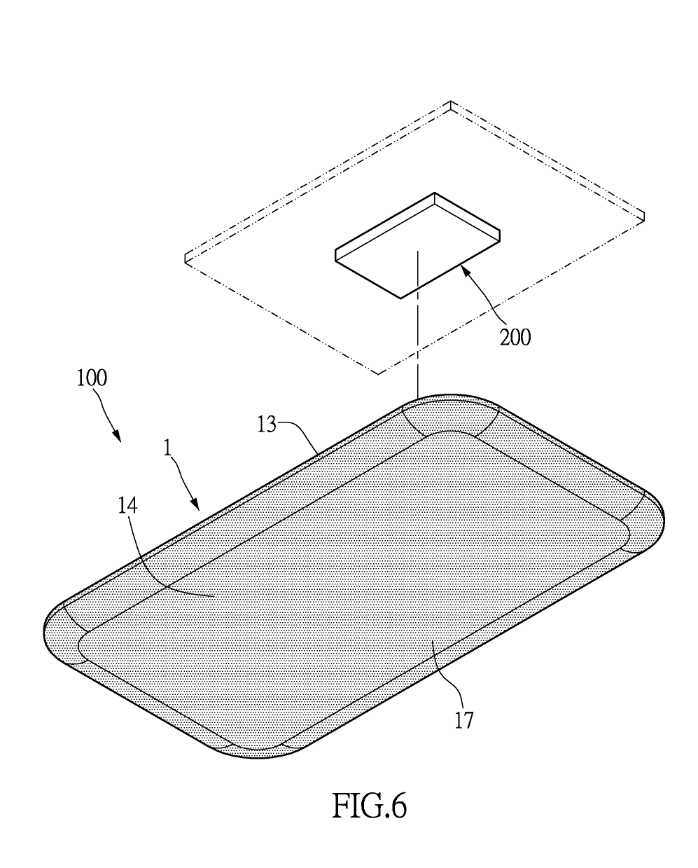

Referring to FIG. 6, in the instant embodiment, the heat dissipating portion 14 of the vapor chamber 1 is formed with sintered metal powder 17. The sintered metal powder 17 can be scattered on any desired area over the heat dissipating portion 14 to enhance heat dissipation in the specific area. The sintered metal power 17 increases dissipation area and therefore improves heat dissipation.

The shell structure 100 is entirely or partially formed with the vapor chamber 1. The heat absorbing portion 13 of the vapor chamber 1 contacts the components in the handheld device and transfers the heat therefrom. The shell structure 100 is capable to guide and dissipate the heat and the heat within the handheld device is rapidly released. The shell structure 100 does not occupy the interior space of the handheld device, saving the volume for other essential components.

Furthermore, the shell structure 100 has a larger size for heat dispersion, ensuring a faster heat dissipation rate.

The descriptions illustrated supra set forth simply the preferred embodiments of the instant disclosure; however, the characteristics of the instant disclosure are by no means restricted thereto. All changes, alternations, or modifications conveniently considered by those skilled in the art are deemed to be encompassed within the scope of the instant disclosure delineated by the following claims.

What is claimed is:

1. A shell structure for a handheld device, comprising:
a vapor chamber taking up at least a portion of the shell structure, wherein the vapor chamber has a heat absorbing portion and a heat dissipating portion, the vapor chamber is vacuumed and filled with fluid, and the vapor chamber has a plurality of capillaries therein.

2. The shell structure for handheld device according to claim 1, wherein the vapor chamber is entirely defined by the shell structure.

3. The shell structure for handheld device according to claim 1, further comprising a casing combined with the vapor chamber.

4. The shell structure for handheld device according to claim 3, wherein the vapor chamber and the casing are engaged by screws, press fit, plug-in, welding, or adhesives.

5. The shell structure for handheld device according to claim 1, further comprising a casing, wherein the vapor chamber is embedded therein.

6. The shell structure for handheld device according to claim 5, wherein the casing is formed with an accommodating space for receiving the vapor chamber therein.

7. The shell structure for handheld device according to claim 5, wherein the vapor chamber and the casing are engaged by screws, press fit, plug-in, welding, or adhesives.

8. The shell structure for handheld device according to claim 1, wherein the heat dissipating portion is formed with a heat dissipation structure.

9. The shell structure for handheld device according to claim 8, wherein the heat dissipation structure includes a plurality of fins or sintered metallic powder.

10. The shell structure for handheld device according to claim 1, wherein the shell structure is flexible.

11. The shell structure for handheld device according to claim 1, wherein the handheld device is one of a mobile phone, a tablet, a laptop, a personal digital assistant, a digital camera, a multi media player and a game player.
